(19) United States
(12) Patent Application Publication
(10) Pub. No.: US 2013/0094120 A1
(43) Pub. Date: Apr. 18, 2013

(54) THIN-FILM CAPACITOR

(71) Applicants: Yuichi Sasajima, Tokyo (JP); Ichiro Hayakawa, Tokyo (JP)

(72) Inventors: Yuichi Sasajima, Tokyo (JP); Ichiro Hayakawa, Tokyo (JP)

(73) Assignee: TAIYO YUDEN CO., LTD., Tokyo (JP)

(21) Appl. No.: 13/642,004

(22) PCT Filed: Mar. 24, 2011
(86) PCT No.: PCT/JP2011/057100

§ 371 Date: Dec. 28, 2012

(30) Foreign Application Priority Data
Apr. 19, 2010 (JP) 2010-096521

(51) Int. Cl. H01G 4/008

(52) U.S. Cl. CPC H01G 4/008
USPC 361/305

(57) ABSTRACT

A thin-film capacitor 10 has an MIM structure in which a lower electrode 14, a dielectric layer 16, and an upper electrode 18 are formed in order on a substrate 12. Of the upper and lower electrodes 18 and 14, at least the upper electrode 18 is formed of a laminated electrode in which a nitride and a metal are laminated. The nitride preferably contains a high-melting point metal, such as Ta or Ti. In addition, the metal laminated along with the nitride is preferably the same as the metal contained in the nitride. Yet additionally, the nitride may contain Si. Thus, by using the laminated electrode containing the nitride in at least the upper electrode 18, identical I-V characteristics can be obtained and reliability is improved without the need for an annealing treatment for characteristic recovery necessary when a Pt electrode is used. Still additionally, adhesion between the dielectric layer 16 and the upper electrode 18 is improved, and therefore, delamination does not occur.

### TECHNICAL FIELD

The present invention relates to an MIM-structured thin-film capacitor in which a lower electrode, a dielectric layer, and an upper electrode are formed in order on a substrate. More specifically, the present invention relates to the maintenance of I-V characteristics and reliability when an electrode alternative to a Pt electrode is used.

### BACKGROUND ART

A thin-film capacitor using BaSrTiO₃ (hereinafter written as BST or BSTO) or the like as a dielectric layer holds promise for use in decoupling applications in SiP (System In Package) embedded components, taking advantage of the nature of low-profile. FIG. 7 illustrates a conventional MIM-structured thin-film capacitor. A thin-film capacitor 100 illustrated in the FIG. 7 has a structure in which a lower electrode 104, a dielectric layer 106, and an upper electrode 108 are laminated in order on a substrate 102.

In the case where a lower electrode 104 and an upper electrode 108 made of Pt and a dielectric layer 106 made of BST are used in the thin-film capacitor 100 having such a structure as described above, hydrogen may accumulate in elements in a process of fabricating the capacitor. Thus, I-V characteristics and capacitance characteristics degrade. In order to recover these characteristics, it is effective to apply a 400° C. or higher heat treatment under a low hydrogen partial pressure. In addition, since the coupling of a Pt/BST interface is considered to be based on an image force, it is difficult to obtain strong coupling. Consequently, the adhesion strength of the Pt/BST interface is low enough to cause delamination therein by a high-temperature bias test or a heat cycle test. Thus, it is difficult to attain reliability compatible with practical use. As a measure against such characteristic degradation as described above, attempts have been made to insert a conductive oxide electrode or the like, though different in dielectric material, in an electrode/dielectric layer interface, as shown in Patent Literatures 1 and 2 mentioned below.

Patent Literature 1 mentioned above relates to the improvement of fatigue characteristics of a Pt/PZT/Pt capacitor used in an FeRAM. According to the technique described in the literature, preventing oxygen defect formation by inserting an SRO film (see reference numerals 5 and 7 in FIG. 1 of the patent publication) in a Pt/PZT interface to secure the diffusion barrier properties of Pb or the like is effective in reducing leakage current to retain hysteresis characteristics. The SRO film can be obtained by forming an amorphous SRO film at low temperature and polycrystallizing the film by heat treatment. In addition, Patent Literature 2 mentioned above relates to a ferroelectric PZT thin-film capacitor. The patent literature discloses inserting such an oxide as Al₂O₃, or SiO₂ or such a nitride as Si₃N₄ in an Al/PZT interface as a buffer film (see reference numeral 7 in FIG. 1 of the patent publication). By the insertion of the buffer film, the diffusion suppression of Al which is a low-melting point metal is made possible even if a high-temperature treatment is performed, thereby enabling the suppression of memory property degradation.

### CITATION LIST

### Patent Literature

Patent Literature 1: Japanese Patent Laid-Open No. 11-195768 (FIG. 1) Patent Literature 2: Japanese Patent Laid-Open No. 5-110009 (FIG. 1)

### SUMMARY OF INVENTION

### Technical Problem

While being superior in oxidation resistance and Schottky characteristics with respect to the dielectric material BSTO, the above-described Pt electrode is much more expensive than other general-purpose metals, and is known to exhibit hydrogen degradation. As a measure against this degradation, a characteristic recovery is attempted by an annealing treatment, as described in the Background Art section. Since Pt readily attracts hydrogen, a Pt/BST/Pt laminated body needs to be coated with a barrier film against hydrogen coming in from the outside after fabrication, in addition to the annealing treatment. Satisfactory reliability cannot always be attained, however, even if such an annealing treatment and a barrier film are applied. In addition, in the technique described in Patent Literature 1 mentioned above, the characteristics of an SRO film inserted in the interface between an electrode and a dielectric layer disadvantageously readily change depending on the composition of Sr and Ru, and the SRO film is high in resistivity, and therefore, causes ESR to become higher. Yet additionally, the technique described in Patent Literature 2 mentioned above uses Al₂O₃, SiO₂, Si₃N₄ or the like as the material of a buffer layer. Since these materials are low-dielectric constant materials, the technique has the disadvantage that a decrease in capacitance is unavoidable.

The present invention has been accomplished in view of the above-described considerations. It is therefore an object of the present invention to provide a thin-film capacitor capable of maintaining I-V characteristics and reliability even when an upper electrode alternative to a Pt electrode is used in an MIM-structured thin-film capacitor.

### Solution to Problem

According to the present invention, a thin-film capacitor includes a lower electrode, a dielectric layer, and an upper electrode laminated in order on a substrate and, of the lower and upper electrodes, at least the upper electrode is formed a laminated electrode composed of a nitride and a metal. In one major embodiment of the present invention, the nitride contains a high-melting point metal. In another embodiment, a metal laminated along with the nitride is the same as the high-melting point metal contained in the nitride. In yet another embodiment, the high-melting point metal is Ta or Ti. In still another embodiment, the nitride contains Si. The above and other objects, features, and advantages of the present invention will become apparent from the following detailed description taken in conjunction with the accompanying drawings.

### Advantageous Effects of Invention

In an MIM-structured thin-film capacitor according to the present invention in which a lower electrode, a dielectric layer, and an upper electrode are laminated in order on a substrate, at least the upper electrode of the upper and lower electrodes is formed of a laminated electrode in which a nitride and a metal are laminated. Consequently, it is possible to obtain excellent I-V characteristics and improve reliability without the need for an annealing treatment after the processing of the MIM capacitor.

### BRIEF DESCRIPTION OF DRAWINGS

FIG. 1 is a cross-sectional view illustrating a laminated structure of a thin-film capacitor according to Embodiment 1 of the present invention.

FIG. 2 is a drawing illustrating one example of a manufacturing process of the thin-film capacitor according to Embodiment 1.

FIG. 3 is a drawing illustrating one example of a manufacturing process of the thin-film capacitor according to Embodiment 1.

FIG. 4 is a drawing illustrating the I-V characteristics of the thin-film capacitor according to Embodiment 1.

FIG. 5 is a drawing illustrating the I-V characteristics of a thin-film capacitor according to a comparative example.

FIG. 6 is a drawing illustrating observed images taken with an ultrasonic microscope after a reliability test of the thin-film capacitors according to Embodiment 1 and the comparative example.

FIG. 7 is a cross-sectional view illustrating the laminated structure of a conventional Pt/BSTO/Pt thin-film capacitor.

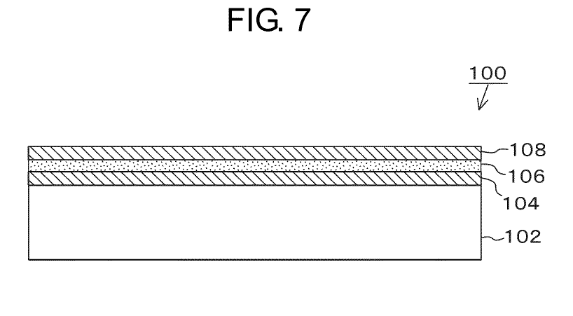

### DESCRIPTION OF EMBODIMENT

Hereinafter, modes for carrying out the present invention will be described in detail according to an embodiment.

### Embodiment 1

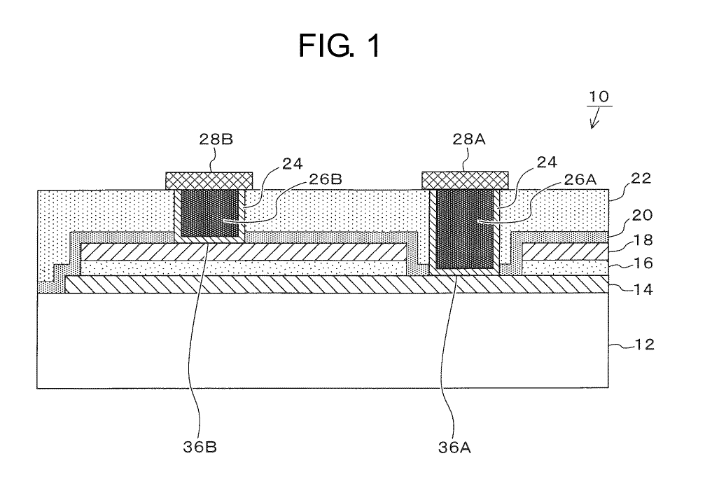

First, Embodiment 1 of the present invention will be described while referring to FIGS. 1 to 6. In general, a metal large in work function is used as an electrode in an MIM-structured thin-film capacitor. Pt is a metal largest in work function but predisposed to accumulate hydrogen which degrades the characteristics of the MIM capacitor, as described above. Accordingly, forming a thin-film capacitor without using Pt is considered to lead to an essential solution. In order to use a metal small in work function as an electrode, the apparent Schottky barrier of the metal with respect to a dielectric material needs to be heightened. Hence, in the present invention, at least an upper electrode of upper and lower electrodes in contact with a dielectric layer is formed of a laminated electrode in which a nitride and a metal are laminated, thereby controlling the band structure of the dielectric material.

First, the structure of a thin-film capacitor of the present embodiment will be described with reference to FIG. 1. FIG. 1 is a cross-sectional view illustrating the laminated structure of the thin-film capacitor of the present embodiment. As illustrated in FIG. 1, a thin-film capacitor 10 has an MIM structure in which a lower electrode 14, a dielectric layer 16, and an upper electrode 18 are laminated in order on a substrate 12. Appropriate portions of an upper surface of the upper electrode 18, except terminal lead-out ports 36A and 36B, are covered with a protective film 20 and photosensitive resin 22. The lower electrode 14 and the upper electrode 18 are connected to external electrodes 28A and 28B by embedded conductors 26A and 26B connected to the terminal lead-out ports 36A and 36B. Barrier films 24 are provided around the embedded conductors 26A and 26B. A plated seed film (not illustrated) is provided in the interface between each barrier film 24 and each of the embedded conductors 26A and 26B.

As the substrate 12, an Si substrate provided with a thermally-oxidized film, for example, is utilized. As the lower electrode 14, a Pt electrode, for example, is utilized. As the dielectric layer 16, BSTO, for example, is used. In addition, as the upper electrode 18, a laminated electrode in which a nitride and a metal are laminated is utilized. Preferably, the nitride contains a high-melting point metal, such as Ta or Ti. More preferably, the nitride contains Si. Film stress in the film formation of a high-melting point metal nitride containing Si (for example, TaSiN) can be lowered, compared with a metal nitride not containing Si (for example, TaN). As a result, stress to be applied to the MIM structure can be reduced, and therefore, it is possible to prevent the degradation of MIM characteristics. As a metal laminated along with the nitride, the same metal as the high-melting point metal contained in the nitride, for example, is utilized. Electrode film formation can be performed continuously by laminating the same metal as the high-melting point metal contained in the nitride. Consequently, transfer between film-forming chambers can be precluded to shorten the process of film formation. It is also possible to prevent a decrease in the adhesion strength between the nitride and the metal. In the present embodiment, a TaSiN/Ta laminated electrode in which TaSiN which is a nitride and Ta which is a metal are laminated is utilized as the upper electrode 18. In addition, as the protective film 20, a TiOₓ/Al₂O₃ film, for example, is utilized, and as the photosensitive resin 22, BCB resin, for example, is utilized. As the material of the embedded conductors 26A and 26B, Cu, for example, is utilized, and as the material of the barrier film 24, TaN/Ta, for example, is utilized. Yet additionally, as the material of the unillustrated plated seed film provided on a surface of the barrier film 24, Cu, for example, is used. Still additionally, as the external electrodes 28A and 28B, Ni/Au laminated electrodes, for example, are utilized.

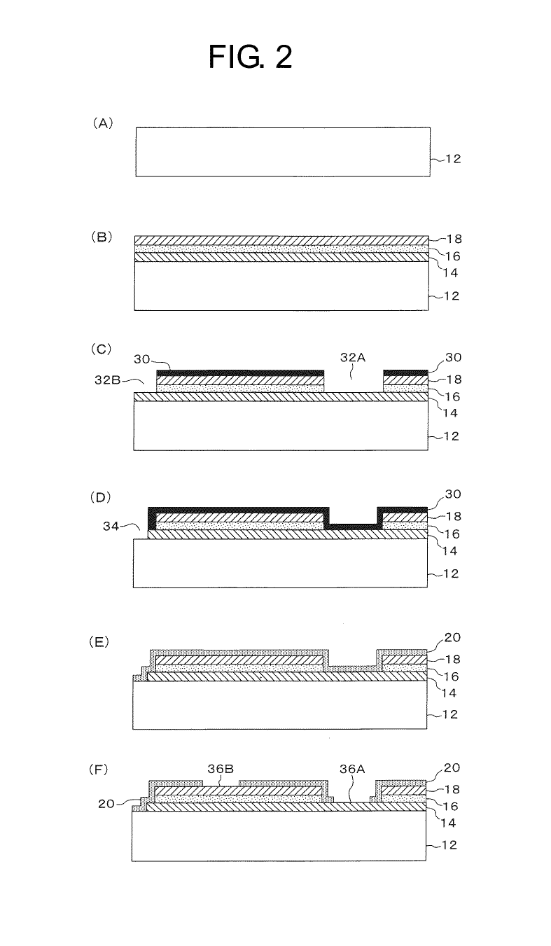

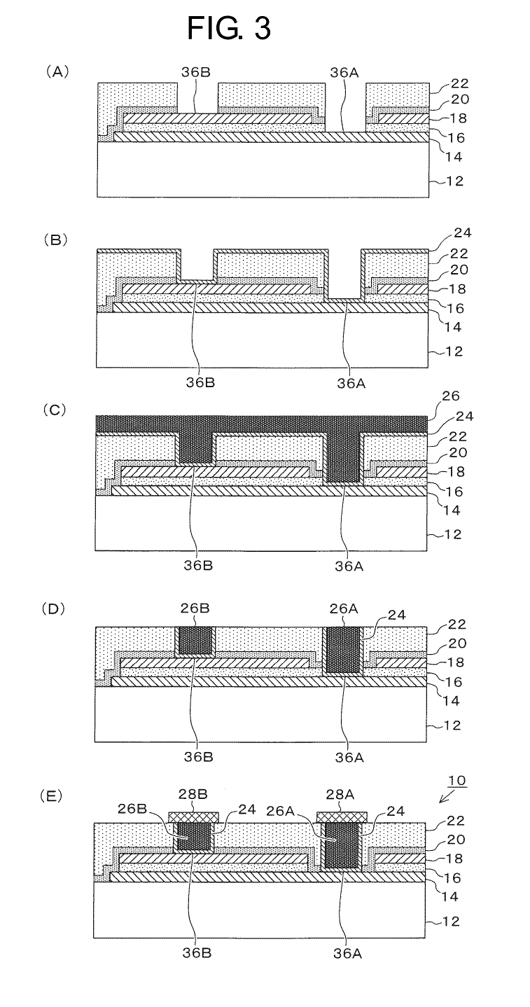

Next, one example of a method for manufacturing the thin-film capacitor 10 of the present embodiment will be described with reference to FIGS. 2 and 3. First, as illustrated in FIG. 2(A), a substrate 12 provided with a thermally-oxidized film and made of Si is prepared. Then, as illustrated in FIG. 2(B), Pt is film-formed as the lower electrode 14, BSTO as the dielectric layer 16, and a TaSiN/Ta laminated film as the upper electrode, in order on the substrate 12 by sputtering, so as to be 250 nm, 150 nm, and 40 nm/100 nm in thickness, respectively. The resistivity of the upper electrode (nitride electrode) 18 is set to, for example, 0.01 Ωcm.

Next, a resist 30 is coated on the upper electrode 18, and the upper electrode 18 and the dielectric layer 16 are processed by photolithography and dry etching, thereby forming processed portions 32A and 32B having desired shapes, as illustrated in FIG. 2(C). Subsequently, the resist 30 is coated once again on the upper electrode 18, including the processed portions 32A and 32B, and the lower electrode 14 is processed by photolithography and dry etching in the same way as in the above-described procedure, thereby forming a processed portion (dicing line portion) 34 having a desired shape illustrated in FIG. 2(D). Thereafter, the resist 30 is removed. Then, as illustrated in FIG. 2(E), TiOₓ/Al₂O₃ is film-formed to a thickness of 2 nm/80 nm as the protective film 20, so as to cover the entire area of a surface exposed after the resist 30 is removed. The terminal lead-out ports 36A and 36B are formed on the protective film 20 by photolithography and dry etching, as illustrated in FIG. 2(F). In the illustrated example, the one terminal lead-out port 36A is in contact with the lower electrode 14, and the other terminal lead-out port 36B is in contact with the upper electrode 18.

A surface of the laminated body formed by the steps described above is coated with BCB resin which is the photosensitive resin 22. Then, as illustrated in FIG. 3(A), holes for forming terminals are formed by photolithography in positions corresponding to those of the terminal lead-out ports 36A and 36B. Note that the photosensitive resin 22 is coated so that the thickness of a portion thereof formed on the upper electrode 18 is approximately 3 μm. Next, as the barrier film 24, a TaN/Ta film is formed by sputtering to a thickness of, for example, 20 nm/20 nm, so as to coat the bottom and side surfaces of the holes formed in the step of FIG. 3(A) and the surfaces of the photosensitive resin 22 (see FIG. 3(B)). In addition, as the plated seed film, a Cu film (not illustrated) is formed by sputtering to a thickness of, for example, 100 nm, and 200° C., 30-minute Cu annealing is applied to the Cu film.

Next, as illustrated in FIG. 3(C), Cu is embedded by Cu electrolytic plating as a plated conductor 26. Then, as illustrated in FIG. 3(D), excess portions of the plated conductor 26 are removed by CMP or the like to form the embedded conductors 26A and 26B. Subsequently, liftoff resist patterning for forming the external electrodes 28A and 28B to be connected to the embedded conductors 26A and 26B is performed (not illustrated). Then, using such a technique as EB deposition, an Ni/Au film is formed as the external electrodes 28A and 28B to a thickness of, for example, 10 nm/100 nm (FIG. 2(E)). Thereafter, the device thus fabricated is divided (diced) into individual pieces having a desired device shape, as necessary, thereby obtaining the thin-film capacitor 10 illustrated in FIG. 1.

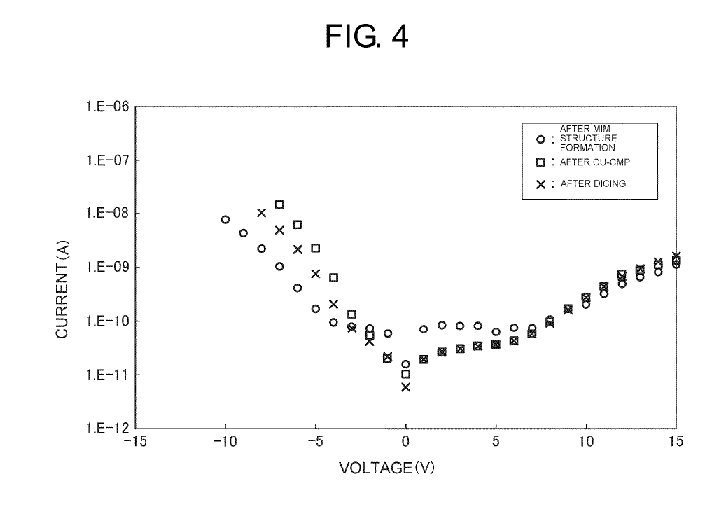

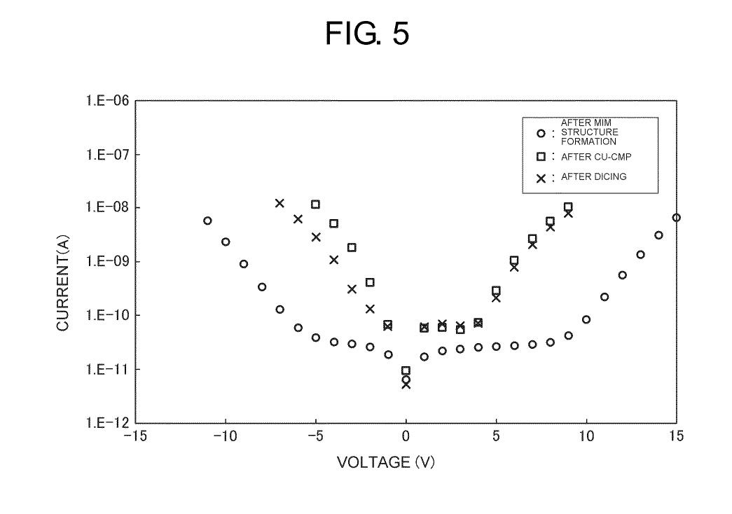

FIG. 4 illustrates the electrical characteristics (I-V characteristics) of the thin-film capacitor 10 of the present embodiment, whereas FIG. 5 illustrates the electrical characteristics of a thin-film capacitor having a conventional structure as a comparative example. Note that the thin-film capacitor of the comparative example has a structure in which the upper electrode 18 of the thin-film capacitor 10 of the present embodiment is replaced with a Pt electrode and that the materials of other locations and the dimensions of other elements are considered to be the same. FIGS. 4 and 5 respectively illustrate characteristics after the MIM formation of the step shown in FIG. 2(C), characteristics after the formation of embedded conductors (after Cu-CMP) of the step shown in FIG. 3(D), and characteristics after unillustrated dicing following the step of FIG. 2(E). In these figures, the axis of abscissas represents voltage [V] and the axis of ordinates represents current [A]. From FIG. 5, it is understood that an increase in leakage current is seen after Cu-CMP in the thin-film capacitor of the comparative example. On the other hand, a compositional difference between the upper electrode 18 and the lower electrode 14 is expressed as the asymmetry property of the I-V characteristics in the thin-film capacitor 10 of the present embodiment. Any degradation due to processing was not observed, however. Any decrease in capacitance due to processing was not observed either in the thin-film capacitor 10 of the present embodiment.

Table 1 below shows the results of a high-temperature bias test and a heat cycle test conducted on the present embodiment and the comparative example. The high-temperature bias test was conducted under the conditions of 125° C. and ±6 V, and the heat cycle test was conducted under the conditions of −55° C. to 125° C. and ±6 V.

TABLE 1

| | High-temperature bias test | | Heat cycle test | |
|---|---|---|---|---|
| Sample | 125° C., 6 V | 125° C., −6 V | 6 V | −6 V |
| Comparative | 1.4 hrs | 1.9 hrs | 0.5 cycles | 0.5 cycles |
| example | | | | |
| Embodiment | 1038 hrs | 1000 hrs or | 1000 cycles | 851 cycles |
| 1 | | longer | or more | |

From the results of Table 1 in both of the high-temperature bias test and the heat cycle test shown above, it is understood that the thin-film capacitor 10 of the present embodiment has a longer service life, compared with the thin-film capacitor of the comparative example having a conventional structure.

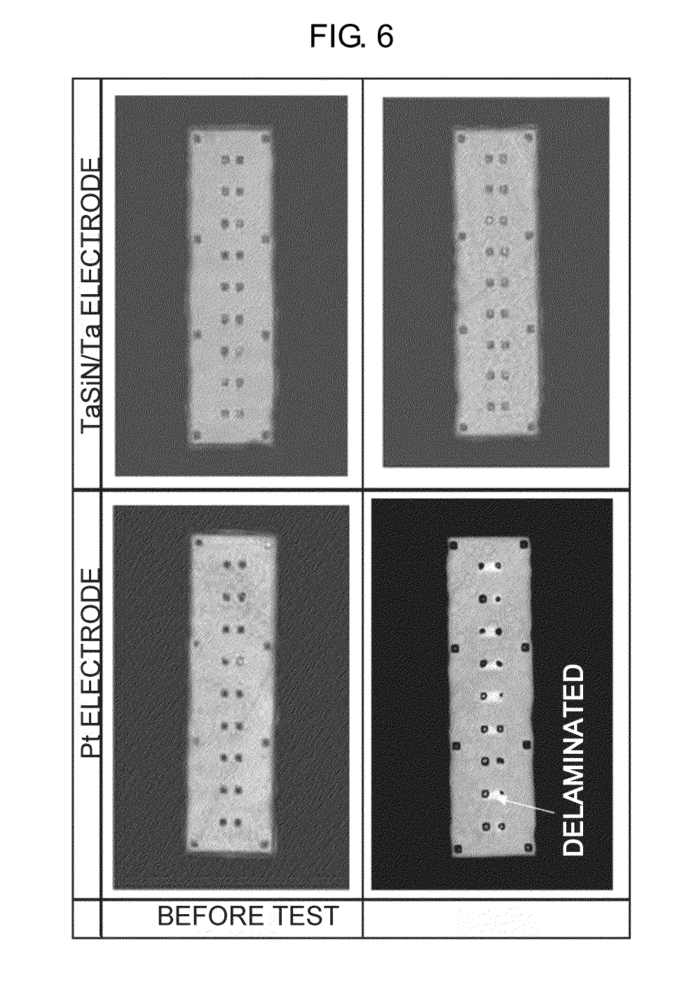

FIG. 6 illustrates images taken with an ultrasonic microscope by observing samples after such reliability tests (high-temperature bias test and heat cycle test) as described above. In FIG. 6, “Pt electrode” represents images of the comparative example, whereas “TaSiN/Ta electrode” represents images of the present embodiment. As illustrated in the figure, delamination was observed in a sample of the comparative example, as shown by an arrow in the lower-left figure, whereas it was confirmed that no delamination was observed in a sample of the present embodiment.

As described above, in the MIM-structured thin-film capacitor 10 according to Embodiment 1 in which the lower electrode 14, the dielectric layer 16, and the upper electrode 18 are formed in order on the substrate 12, the upper electrode 18 is formed of a laminated electrode in which a nitride and a metal are laminated. Accordingly, the thin-film capacitor 10 has the following advantageous effects: (1) Equivalent characteristics can be obtained without the need for an annealing treatment for characteristic recovery necessary when Pt is used in the upper electrode 18. It is also possible to subject steps subsequent to the film-formation of the dielectric layer 16 to a low-temperature process. (2) Adhesion between the dielectric layer 16 and the upper electrode 18 is improved, and therefore, delamination does not occur. (3) A service life more than 100 times longer than that of a conventional structure is available with respect to a high-temperature bias test and a heat cycle test, and reliability is greatly improved. (4) Hydrogen degradation can be suppressed without necessarily providing the protective film 20 made of Al₂O₃ or the like, since the upper electrode 18 utilizing a nitride has antihydrogen barrier properties.

Note that the present invention is not limited to the above-described embodiment, but may be modified in various other ways without departing from the gist of the invention. Examples of the modification include the following: (1) The shapes and dimensions shown in the above-described embodiment are illustrative only, and may be modified as appropriate according to need. (2) The materials shown in the above-described embodiment are also illustrative only, and may be modified as appropriate, to the extent of exercising the same effects. For example, although TaSiN is utilized as a nitride for composing the upper electrode 18 in the above-described embodiment, this is also illustrative only. Alternatively, the nitride may contain a high-melting point metal (for example, Ti) other than Ta. The nitride may also contain Si, as necessary. In addition, although in the above-described embodiment, the same metal as the high-melting point metal contained in the nitride is used as a metal laminated along with the nitride, this is also illustrative only. Alternatively, a metal different from the metal contained in the nitride may be utilized.

(3) The composition of the nitride need not necessarily be constant, but may be made gradient in the thickness direction of the nitride. For example, electrode resistance, and consequently, the ESR of the MIM capacitor can be controlled by making the composition gradient. In addition, the present embodiment has the advantage that not only stress reduction but also continuous film formation is possible by gradating the composition of the nitride toward the metal laminated thereon, so as to be identical to the composition of the metal. (4) Although in the above-described embodiment, a laminated electrode composed of a nitride and a metal is used for the upper electrode 18, a laminated electrode composed of a nitride and a metal may also be used for the lower electrode 14. (5) Although in the above-described embodiment, an insulating antihydrogen barrier film (protective film 20), such as a TiOₓ/Al₂O₃ film, is provided, the protective film 20 may only be provided as necessary. This is because the nitride itself used in the upper electrode 18 also functions as an antihydrogen barrier film. Thus, it is possible to impart resistance to hydrogen diffusion from the outside after device formation. (6) The nitride may have either insulation properties or conductive properties. The resistivity of the nitride can be controlled by means of the film composition thereof according to ESR required of elements.

### INDUSTRIAL APPLICATION

According to the present invention, an MIM structure in which a lower electrode, a dielectric layer, and an upper electrode are formed in order on a substrate is configured so that at least the upper electrode of the lower and upper electrodes is formed of a laminated electrode in which a nitride and a metal are laminated. Consequently, excellent I-V characteristics and reliability can be obtained without the need for an annealing treatment after the formation of the MIM structure. Thus, the MIM structure can be applied to a thin-film capacitor. The MIM structure is particularly preferred as a thin-film capacitor for high-capacitance decoupling applications.

### REFERENCE SIGNS LIST

10: Thin-film capacitor, 12: Substrate, 14: Lower electrode, 16: Dielectric layer, 18: Upper electrode, 20: Protective film, 22: Photosensitive resin, 24: Barrier film, 26: Plated conductor, 26A, 26B: Embedded conductor, 28A, 28A: External electrode, 30: Resist, 32A, 32B, 34: Processed portion, 36A, 36B: Terminal lead-out port, 100: Thin-film capacitor, 102: Substrate, 104: Lower electrode, 106: Dielectric layer, 108: Upper electrode

What claimed is:

1. A thin-film capacitor comprising: a lower electrode, a dielectric layer, and an upper electrode formed in order on a substrate, wherein at least the upper electrode of the lower and upper electrodes is formed of a laminated electrode composed of a nitride and a metal.

2. The thin-film capacitor according to claim 1, wherein the nitride contains a high-melting point metal.

3. The thin-film capacitor according to claim 2, wherein the metal laminated along with the nitride is the same as the high-melting point metal contained in the nitride.

4. The thin-film capacitor according to claim 2, wherein the high-melting point metal is selected from one of the group consisting of Ta and Ti.

5. The thin-film capacitor according to claim 1, wherein the nitride contains Si.
